(19) United States
(12) Patent Application Publication
(10) Pub. No.: US 2006/0121396 A1
(43) Pub. Date: Jun. 8, 2006

(54) Method for exposing a substrate with a beam

(75) Inventors: Heike Gauglitz, Jena (DE); Michael Gehre, Jena (DE); Peter Hahmann, Jena-Drackendorf (DE); Michael Hopp, Kahla (DE); Detlef Melzer, Jena (DE)

Correspondence Address: HOUSTON ELISEEVA, 4 MILITIA DRIVE, SUITE 4, LEXINGTON, MA, 02421, US

(73) Assignee: Leica Microsystems lithography GmbH, Jena (DE)

(21) Appl. No.: 11/289,030

(22) Filed: Nov. 29, 2005

(30) Foreign Application Priority Data
Dec. 8, 2004 (DE) DE102004058967.4-

(51) Int. Cl. G03F 7/20

(52) U.S. Cl. 430/396; 430/397

(57) ABSTRACT

A method is disclosed in which the speed of the substrate carrier system 50 is changed during exposure depending on the exposure pattern density. The substrate carrier system 50 defines a track curve 60, whereby the exposure pattern is exposed within a band (62₁, 62₂, . . . 62₃) around the track curve.

### RELATED APPLICATIONS

This application claims priority to German patent application number DE 10 2004 058 967.4-51, filed Dec. 8, 2004, which is incorporated herein by reference in its entirety.

### FIELD OF INVENTION

The invention relates to exposing on a substrate with a beam.

### BACKGROUND OF THE INVENTION

In SB3xx systems from Leica Lithography GmbH, the maximum possible constant table speed is calculated for each exposure strip by simulating the exposure cycle in advance.

The importance of speed in this mode is made clear by publication JP08/236,420AA. Strip width is determined in advance such that a minimum or maximum speed is neither over- nor undershot. However, adjusting the speed to the density of the image contents is not considered.

Publication JP000006196394AA also describes the interplay between various articulation systems that make possible continuous table movement. However, the speed is intentionally kept constant.

The solution described in JP000006151287AA takes into account the varying density of image contents in so far as parts are to be exposed repeatedly at longer exposure times. However, this is only meant to ensure that the exposure process can follow the table movement without having to take into account the time required for twice positioning on one and the same substrate.

### SUMMARY OF THE INVENTION

The object underlying the invention is to create a method for exposing on a substrate with a beam, by which the throughput is increased when exposing the substrate.

This object is solved by a device with the characteristics in claim 1.

The method is advantageous because the speed of the substrate carrier system can be adjusted during exposure depending on the density of the exposure pattern. The substrate carrier system defines a track curve, whereby the exposure pattern is exposed within a band around the track curve.

The beam system comprises a primary deflector system and a micro deflector system, whereby the primary deflector system pre-positions the beam on the individual partial working field within the track curve in order to produce the exposure pattern there. The track curve is a strip on the substrate that exhibits a surface that is smaller than that of the substrate itself.

The change in speed at which the track curve is defined is first determined based on the density of the exposure pattern, dependent on parameters of the substrate carrier system and parameters of the beam system. The beam system parameters comprise the response times and deflection ranges of the deflection system and the overhead time of the electronic control mechanism.

The lag time for correcting the position of the substrate carrier system and of the beam system to ensure precise positioning of the exposure pattern on the substrate is determined based on the local speed of the substrate carrier system.

The beam system exhibits a primary deflector system and a micro deflector system, whereby the primary deflector system pre-positions the beam on the individual partial working field within the track curve in order to produce the exposure pattern there. The track curve forms a strip on the substrate that exhibits a surface that is smaller than that of the substrate itself.

The change in speed at which the track curve is defined is first determined based on the density of the exposure pattern, dependent on parameters of the substrate carrier system and parameters of the beam system. The beam system parameters comprise the maximum permissible acceleration and the minimum and maximum speed of the substrate carrier system. The parameters of the beam system comprise the response times and deflection ranges of the deflection systems and the overhead time of the electronic control system.

The lag time for correcting the position of the substrate carrier system and of the beam system to ensure precise positioning of the exposure pattern on the substrate is determined based on the local speed of the substrate carrier system.

Further advantageous developments of the invention may be found in the subclaims.

The above and other features of the invention including various novel details of construction and combinations of parts, and other advantages, will now be more particularly described with reference to the accompanying drawings and pointed out in the claims. It will be understood that the particular method and device embodying the invention are shown by way of illustration and not as a limitation of the invention. The principles and features of this invention may be employed in various and numerous embodiments without departing from the scope of the invention.

### BRIEF DESCRIPTION OF THE DRAWINGS

In the accompanying drawings, reference characters refer to the same parts throughout the different views. The drawings are not necessarily to scale; emphasis has instead been placed upon illustrating the principles of the invention. Of the drawings:

The diagrams show schematically the object according to the invention, which will be described below on the basis of the figures. They show:

FIG. 1 a schematic representation of the construction of an entire electron beam lithography system;

FIG. 2 a schematic representation of a lithography system with a resting beam system and moving substrate carrier system;

FIG. 3 a top view of the substrate carrier system, whereby the substrate in this case is a mask;

FIG. 4 a top view of the substrate carrier system, whereby the substrate in this case is a wafer; and

FIG. 5 a schematic representation of a band on a substrate, in which the exposure pattern is created in the corresponding partial working fields.

### DETAILED DESCRIPTION OF THE PREFERRED EMBODIMENTS

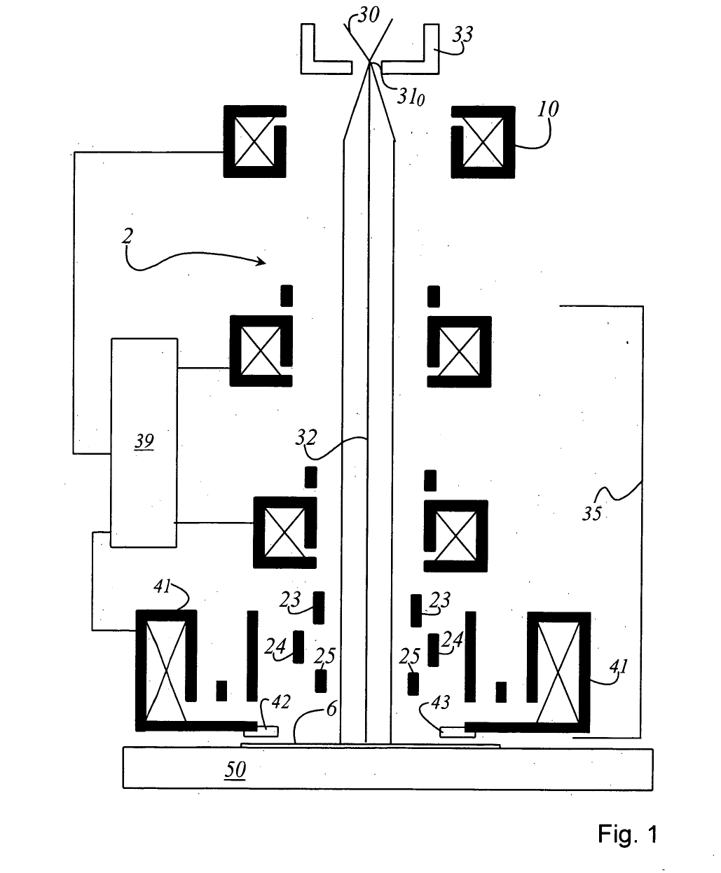

FIG. 1 shows a schematic of the construction of an entire maskless electron beam lithography system. Although the following description is limited to electron beams, this should not be viewed as a limitation on the invention. It is obvious that the invention for exposing substrates with particle beams is also suitable for light beams (lasers).

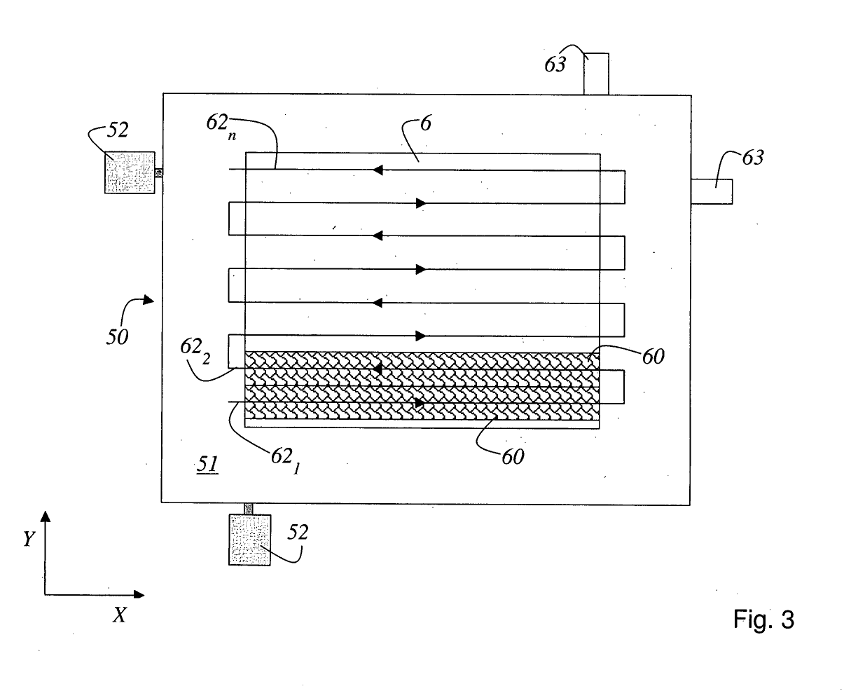

An electron cannon 30 generates an electron beam 31 that spreads out in the direction of an electron optical axis 32. The electrons emitted by the electron cannon 30 exhibit a source crossover 31. The electron cannon 30 is connected to a beam centering device 33 that aligns the electron beam 31 symmetrically around the optical axis 32. After the beam centering device, the electron beam 31 passes through an illumination condenser 10, which forms a parallel beam from the initially divergent electron beam. A beam forming system 35 is provided in the direction of spread of the electron beam 35 toward a substrate 6. Furthermore, the system comprises a primary deflector system 25 and a micro deflector system 23, whereby the primary deflector system 25 pre-positions the beam within the track curve (see FIG. 3) on the substrate 6 on partial working fields 6a. The micro deflector system 23 ensures fine positioning of the electron beam 31 within each partial working field 6a in order to generate an illumination pattern there. The independently controllable primary deflector system 25 and the micro deflector system are advantageously used to optimally create separate slow and fast deflection processes. Fast deflection processes in the MHz to GHz frequency range are required in order to keep the position of the electron beam 31 constant on a substrate 6 that does not move uniformly for the time needed for one exposure step or exposure phase respectively, and subsequently to jump to the next partial working field 6a in a very short period of time. The objective lens 41 has a scanning hypsometry system 42 at the target or beam base point of the electron beam at the target 6. The hypsometry system serves to detect unevennesses in the substrate 6 (e.g., wafer, mask) as well as such height fluctuations as can be caused by a substrate carrier system 50. A detector 43 is located close to the beam base point for the particles scattered back from the target 6. This detector 43 serves to determine the position of marks on the substrate 6 for the purpose of covering several exposure planes, and to calibrate the control elements of an exposure system, respectively. Furthermore, there is a corrective lens 24 in the lower region of the corpuscular beam device 2. The corrective lens 24 serves to dynamically correct the focus, the size of the image field, and the rotation of the image field rotation during exposure of the variably movable substrate 6. The corrective lens 24 enables the correction of errors that may be brought about by height fluctuations in the substrate 6 as well as by variable spatial charges in the column region.

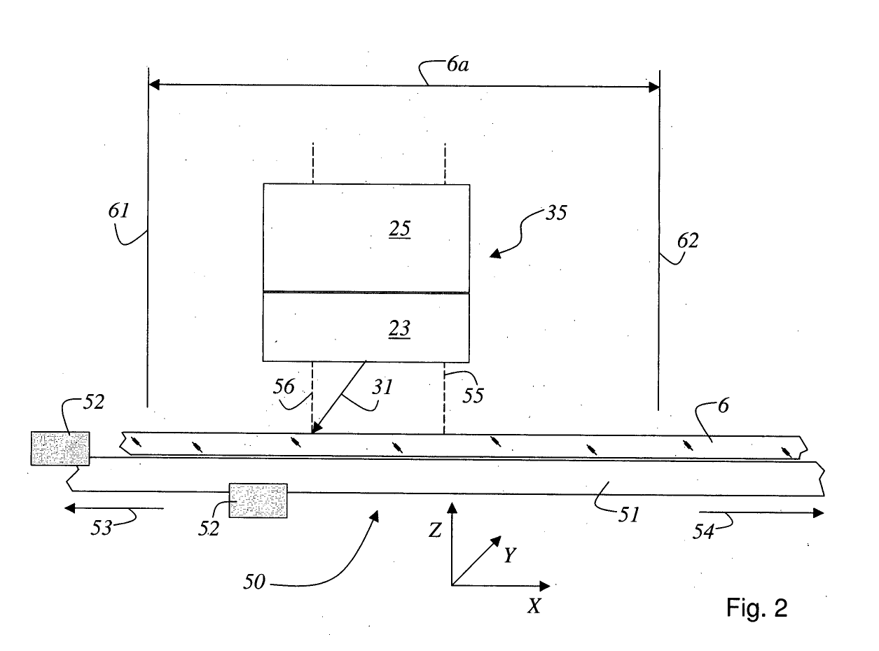

In the very simplified exemplary schematic representation (see FIG. 2) of such a system (Leica SB3xx electron beam exposure system) an individual beam from the resting beam system 35 is brought into congruence by means of a three-step process with the point to be exposed on the substrate carrier system that continuously moves forward or backward in X-direction. The primary deflection system 25 ensures pre-positioning of the beam in the positioning range of the faster micro deflection system 23. For this purpose, the data for the track curve to the exposed (substrate segment, strip) are first divided into two-dimensional arrays (columns in the Y-direction, lines in the X-direction) of partial working fields 6a, which in each case correspond to a position of the primary deflection system, and from which fine positioning of the beam by means of the micro deflection system 23 is achieved. Beam tracking ensures maintenance of the exposure point set by the primary deflection system 25 and/or the micro deflection system 35b on the substrate 6 during the entire time that this point is being exposed. The primary deflection system 25 and table position are synchronized at the beginning of each partial working field 6a. Beam tracking is then reset. In the regions with a particularly high density of exposure patterns to be exposed and/or in the case of high table speeds, it may occur that the tracking range of the beam tracker is inadequate to expose the entire contents of a partial working field 6a, so that further such resets of the beam tracker are required within the affected partial working field 6a. The substrate carrier system 50 largely comprises a table 51 onto which the substrate 6 can be placed. The table can be moved by means of a motor 52 in an X-direction X and in a Y-direction Y.

All operations that are depicted and others required for the exposure cycle (adjusting the beam form and imaging sharpness: intermediate adjustments for height correction, etc.) required time, during which the table 51 continues to move. Tracking by means of the primary deflection system 25 with the table that has just been described, is only possible within certain limits, which in FIG. 2 are designated as the left limit stop 61 of the primary deflection system 35a. By the time the left limit stop 61 has been reached, processing of the current partial working field 6a by the beam tracker must have been totally completed, because otherwise exposure is interrupted, and can only be restarted after the table 6 has been repositioned to the corresponding position, which requires a great deal of time. Top table speed is limited as a result (condition of performance). On the other hand, it is possible that after several successive weakly covered partial working fields 6a (illumination pattern density to be written in a field) and/or too low a table speed, the X-position of the next field to be processed is not yet in the positional range of the primary deflection system 25. The partial working field 6a would then fall outside the right limit stop 62 of the primary deflection system 25, so that exposure is subjected to an additional unfunctional hold time. The direction of excursion of the table is indicated by the arrow 53, and the increasing X-direction by the arrow 54.

Because the time needed for fixing the system and processing parameters to be used while exposing of the exposure pattern within a band 60 around a track curve 62₁, 62₂, . . . 62ₙ (for more, see FIG. 3) are already completely established, the maximum possible table speed can in principle be calculated in advance on this basis with reference to the above-mentioned condition of performance. Because of the complexity of the exposure process, and because of indeterminate influences, this is, however, only possible by approximation. With variable table speed, productivity reserves may be developed if one allows for variable table speed during exposure, and in this manner compensates for density fluctuations in the illumination pattern that are present in the geometry to be exposed. A zero-position 55 of the electron beam 31 as well as an X-position of the electron beam 31 are also represented in FIG. 2.

FIG. 3 shows a top view of the substrate carrier system 50, whereby the substrate 6 in this case is a mask. The change in speed with which track curve 62₁, 62₂, . . . 62ₙ is defined is first determined based on the exposure pattern density, dependent on the parameters of the substrate carrier system and the parameters of the beam system. The exposure pattern is exposed within a band 60 around a track curve 62₁, 62₂, . . . 62ₙ. As a result of the multiplicity of bands 60 on the substrate 6, the entire surface of the substrate 6 can largely be covered. The position of the substrate carrier system 50 in the X-direction and in the Y-direction is determined by a suitable path measuring system 63. The path measuring system 63 can, for example, be implemented as a laser path measurement system.

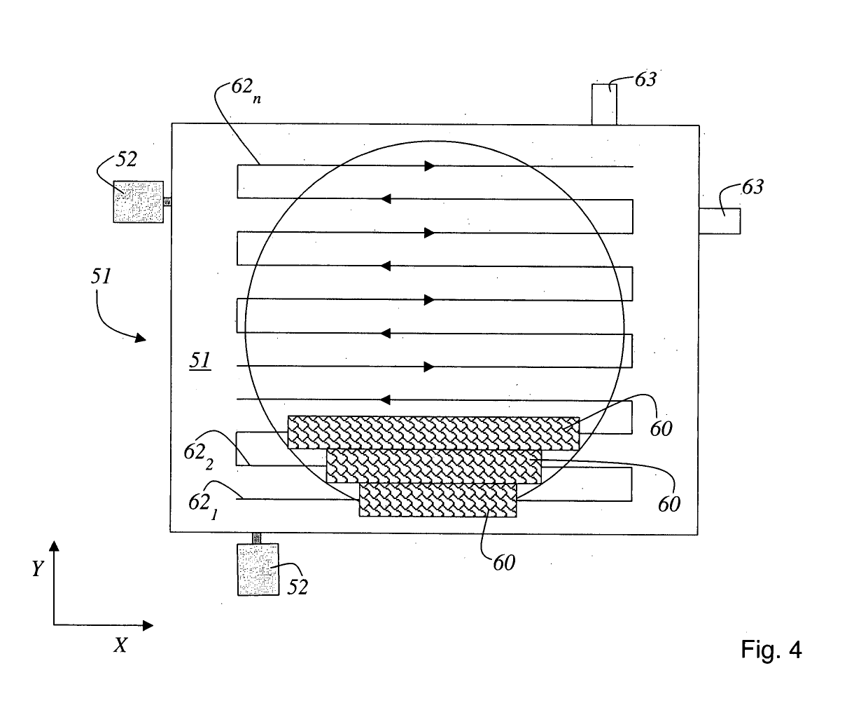

FIG. 4 shows a top view of the substrate carrier system 50, whereby the substrate in this case is a wafer. The exposure pattern is exposed within a band 60 around each individual track curve 62₁, 62₂, . . . 62ₙ. The bands are of variable length because of the round configuration of the wafer so that in each case only one surface of the wafer is covered by the exposure. As a result of the multiplicity of bands 60 on the substrate 6, the entire surface of the substrate 6 can largely be covered.

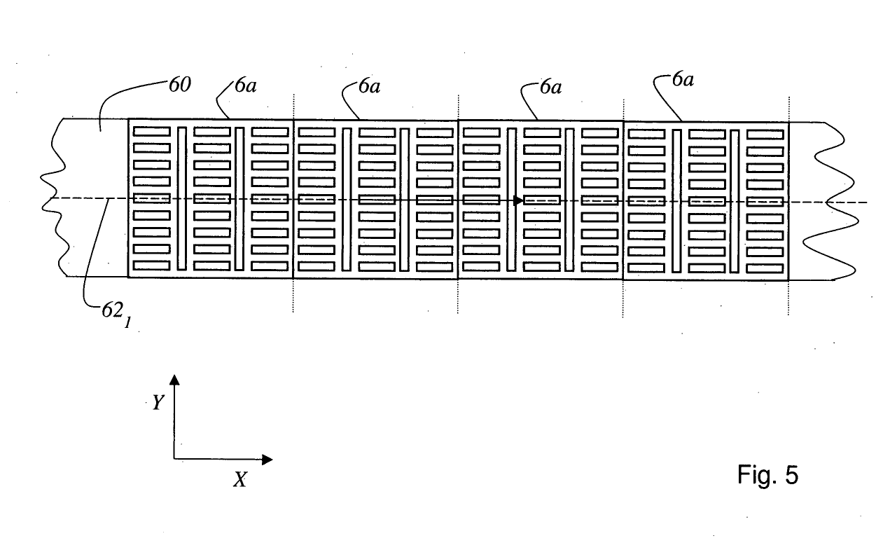

FIG. 5 is a schematic representation of a band 60 on a substrate 6, in which the exposure pattern 70 is produced in the corresponding partial working fields 6a. Although the band 60 represented in FIG. 5 is implemented as a rectangle, this should not be interpreted as a limitation of the invention. It is obvious that the track curve 62₁ may also take a form that does not have straight lines, and the breadth of the band is then distributed symmetrically around the band 60.

A mathematical model (embodiment of the invention) for controlling the speed can be described as follows:

[x_{A}, x_{E}] describe control intervals within which the speed is to be changed.

v(x), xε[x_{A}, x_{E}] Is the control function for table speed at Point X.

$$\frac{1}{{x}_{E} - {x}_{A}} {\int }_{{x}_{A}}^{{x}_{E}} v ( x ) ⅆ x$$

the average speed above [x_{A}, x_{E}] can be calculated using the formula herein.

The task is now to find the maximum speed at which the table or the substrate carrier system, respectively, may be moved. The speed is dependent on the exposure pattern that is to be written in each partial working field.

$$\frac{1}{{x}_{E} - {x}_{A}} {\int }_{{x}_{A}}^{{x}_{E}} v ( x ) ⅆ x \to max !$$

Maximization of throughput speed is determined by the above formula.

A series of secondary conditions determine the speed at which the substrate carrier system 50 can be moved.

The class of functions for the control function v(•) of the speed is determined by:
vεC[x_{A},x_{E}], 0≦vₘᵢₙ≦|v(x)|≦vₘₐₓ, xε[x_{A},x_{E}]:
\overline{x}, {double overscore (x)}ε[x_{A},x_{E}] [symbol] |v(\overline{x})−v({double overscore (x)})|≦f(|\overline{x}−{double overscore (x)}|), f monotonically increasing, f(0)=0, e.g.,
Δv is the maximum speed change at intervals of the value Δx (both preset);
   further conditions set by drive motor control include adequately smooth transitions.

Performance and secondary conditions of a system with variable speed control:
h_{A} is the position of the primary deflection system 23 at the time that exposure on the substrate 6 is begun;
t(x), xε[x_{A}, X_{E}] is the time necessary to accomplish all exposure tasks when the table position X passes the position h_{A} of the primary deflection system 23 such that exposure continues to be feasible (i.e., so that all necessary tasks are completed before X leaves the positioning range of the primary deflection system 35a);
which results in the performance condition:

$$t ( x ) {\int }_{{x}_{A}}^{x} v ( ξ ) ⅆ ξ \leq {( x - {x}_{A} )}^{2} , x ε [ {x}_{A} , {x}_{E} ]$$

The following characteristic features result:

t(•) is dependent on v(•) (additional resetting of the beam system, hold times at the right stop limit 62 of the primary deflection system 23)

t(•) can only be estimated (complexity of the actual interplays; indeterminate influences)

One possibility for solving this problem is to first establish a specialized target model. Then one must determine a preliminary solution for a suitable model relaxation. Iterations of the exposure simulation follow until an allowable solution for the target model is achieved.

Model relaxations for determining preliminary solutions can, for example, be obtained by allowing more general control functions v in comparison with the target model (e.g., a greater number and/or more freely positionable control points). By the same token, the use of local limit speeds instead of global feasibility conditions is also possible.

Examples of speed control according to this model are described in the following. The circumstances of drive motor control of this system do not permit continuous realization (such as in the sense of defining a curve) of a suitably calculated speed profile, but only permit the setting of a certain number of discrete control points x_{A}=x₀<x₁< . . . <xₙ=x_{E} for which a certain speed is to be achieved. This should not, however, be interpreted as a limitation of the invention. Whenever the drive motor control permits, continuous realization, i.e., continuous control of the speed, is also possible. The actual realized speed between these switch points cannot be changed; however, it is calculable with adequate precision, monotonically increasing or decreasing at increasing or decreasing speed from one control point to the next, and moreover monotonically evenly dependent on speeds in the control points (i.e., \overline{v}(xᵢ₋₁)≦v(xᵢ₋₁)ˆ\overline{v}(xᵢ)≦v(xᵢ) [symbol] \overline{v}(x)≦v(x)∀xε[xᵢ₋₁, xᵢ], analogous for “≧”).

Example 1 relates to control at a constant speed that is integrated in the model.

### EXAMPLE 1

### A Constant Speed

Model:

v(x)≡const

Relaxation:

The maximum speed possible in the densest partial working field 6a (high exposure pattern density) taking into account the secondary technical conditions (maximum table speed, permissible maximum number of additional resets of the beam tracker, etc.) yields the preliminary solution.

Iteration:

Simulation of the exposure process. The initial speed is decreased for as long as it takes to do the exposure.

### Example 2

### Preset Control Points

Model:

The control points x_{A}=x₀<x₁< . . . <xₙ=x_{E} are preset and are all laid out on the columns and limits of the partial working field. These may, for example, have been determined in a preparatory step based on a preset control point minimum interval ax such that Δx≦xᵢ−xᵢ₋₁, i=1, . . . , n, applies. The maximum allowable change in speed for all segments Aᵢ=[xᵢ₋₁, xᵢ] so defined by segment length aᵢ=xᵢ−xᵢ₋₁, i=1, . . . n, is to be uniformly the same as Δv.

Relaxation:
The maximum speed in the densest partial working field 6a of each segment is determined (as in Example 1). The resulting speeds are v₁, . . . , vₙ. If one then sets wᵢ=v(xᵢ), i=0, . . . , n, one then gets the following linear optimization problem for determining a piecewise monotonic preliminary solution v(•):

$${\sum }_{i = 1}^{n} {a}_{i} ( {w}_{i - 1} + {w}_{i} ) \to max !$$

under secondary conditions
α) wᵢ≦vᵢ, wᵢ₋₁<vᵢ, i=1, . . . n,
β) |wᵢ₋₁−wᵢ|≦Δv, i=1, . . . n.

It is notable that the concrete form of v(•) between the control points have no influence on the optimization of a solution to this problem—in so far as the above-mentioned monotonic characteristics are met.

Iteration:

Simulation of the exposure cycle. If exposure is recognized as not being feasible, the speed in the current or previous segment is decreased, permissibility in the sense of relaxation is created, and a renewed iteration done. Criteria for the selection of the segment in which the speed is decreased result from the course of the iteration.

While this invention has been particularly shown and described with references to preferred embodiments thereof, it will be understood by those skilled in the art that various changes in form and details may be made therein without departing from the scope of the invention encompassed by the appended claims.

What is claimed is:

1. Method for exposing on a substrate 6 with a beam system 35 and a substrate carrier system 50, wherein the speed of the substrate carrier system 50 is changed depending on an exposure pattern density during exposure.

2. Method according to claim 1, wherein the substrate carrier system 50 defines a track curve 62₁, 62₂, . . . 62ₙ, and wherein the exposure pattern is exposed within a band 60 around the track curve 62₁, 62₂, . . . 62ₙ.

3. Method according to claim 1, wherein the beam system 35 exhibits a primary deflection system 25 and a micro deflection system 23, whereby the primary deflection system pre-positions the beam 32 within the track curve 62₁, 62₂, . . . 62ₙ in partial working fields 6a, and the micro deflection system 23 fine positions the beam 32 within each partial working field 6a in order to produce an exposure pattern there.

4. Method according to one of claims 1, wherein the track curve 60 is a strip on the substrate 6, and which exhibits a surface that is smaller than that of the substrate 6 itself.

5. Method according to claim 4, wherein the track curve 60 lies along a plane that is parallel to the surface of the substrate 6.

6. Method according to claim 1, wherein the change in speed with which the track curve 60 is defined is determined in advance based on the exposure pattern density, depending on parameters of the substrate carrier system 50 and on parameters of the beam system 35.

7. Method according to claim 4, wherein the parameters of the substrate carrier system 50 comprise the maximum permissible acceleration and the minimum and maximum speed of the substrate system 50.

8. Method according to claim 4, wherein the parameters of the beam system 35 comprise the response time and deflection range of the deflection systems and the overhead time of the electronic control system 39.

9. Method according to one of claims 1, wherein the positional correction lag-time of the substrate carrier system and of the beam system are determined dependent on the local speed of the substrate system for precise positioning of the exposure pattern on the substrate.

10. Method according to one of claims 1, wherein the beam is a corpuscular beam.

11. Method according to claim 10, wherein the corpuscular beam is an electron beam.

12. Method according to one of claims 1, wherein the substrate is a mask for semiconductor production.

13. Method according to one of claims 1, wherein the substrate is a wafer.
